(19) United States
(12) Patent Application Publication
(10) Pub. No.: US 2003/0174554 A1
(43) Pub. Date: Sep. 18, 2003

(54) Security container for medicines and system for filing prescriptions

(76) Inventors: Edward Simone Dunstone, Alexandria (AU); Andrew Peter Bradley, Castlecrag (AU)

Correspondence Address: LADAS & PARRY, 26 WEST 61ST STREET, NEW YORK, NY, 10023, US

(21) Appl. No.: 10/344,875

(22) PCT Filed: Aug. 15, 2001
(86) PCT No.: PCT/AU01/01012

(30) Foreign Application Priority Data
Aug. 17, 2000 (AU) PQ 9460
Oct. 27, 2000 (AU) PR 1043

(51) Int. Cl. G11C 7/00

(52) U.S. Cl. 365/200

(57) ABSTRACT

The present invention discloses a security container (1, 20) for medicines and the like, a method of dispensing the medicines from the container, a system of filling prescriptions for medicines, and a method of filling prescriptions. The security container has a lockable lid actuated by a biomedical attribute of the patient (e.g. a fingerprint or eye scan). Preferably a portable device (30) is used to transmit a wireless signal to permit the unlocking and the portable device (30) includes a finger print sensor (32). A data log of dosage history is able to be downloaded from a microprocessor (40).

### FIELD OF THE INVENTION

The present invention relates to the secure containing and subsequent dispensing of prescription medicine or pharmaceuticals to a prescribed patient or caregiver. This is achieved via a biological attribute of the patient or caregiver, such as their fingerprint, either directly, or via a wireless connection to a portable or mobile device held by the patient or caregiver. The mobile device then performs authentication of the patient or caregiver using an appropriate biometric reader, so that they can obtain access to the prescription medicines. The present invention also relates to a secure locking and dispensing mechanism that is an integral part of the lid or cap of a conventional medicine container. A medicine distribution system is also disclosed.

### BACKGROUND ART

The prior art describes a number of childproof containers for the storage of medicines or dangerous chemicals. For example U.S. Pat. No. 3,771,681 discloses a childproof container cap, U.S. Pat. No. 3,827,592 discloses a childproof container closure, and U.S. Pat. No. 3,825,143 discloses a childproof medicine vial. However, the lock mechanisms used in the prior art are not totally secure, in that once a person knows how to open the lid, this information can be transferred to anyone who is then able to repeatedly open the container. Therefore, the containers are not secure against more mature age children or adults.

The prior art also describes a number of secure cabinets for medicines or dangerous chemicals. For example U.S. Pat. No. 5,351,818 discloses a medicine box which contains a number of pill bottles and a weekly pill dispenser counter whilst U.S. Pat. No. 5,047,948 discloses a medication dispensing system that is portable, secure, and appropriately dispenses medicines to patients. However, there are a number of problems with this prior art in that the security on the cabinet is separate to the medicine containers. Therefore, once access has been gained to the cabinet there is unrestricted access to all the medicines contained therein. In addition, these cabinets are expensive and, by their very nature, significantly larger in size that the medicine containers held within. The prior art also describes several wireless or telephony based authentication mechanisms. For example U.S. Pat. No. 5,668,876 discloses a user authentication method and apparatus for providing a unique response code to allow a user access to a service via a communications device. However, this prior art does not disclose how to gain access to secure containers used for the storage of medicines, dangerous chemicals or the like.

### OBJECT OF THE INVENTION

It is the objection of the present invention to substantially overcome, or at least ameliorate, the above mentioned difficulties by the provision of a container with a lid that is secure, and is only operable by use of a biomedical attribute of the user. A method of dispensing medicines from the security container, a system for filling prescriptions and a method of filling prescriptions are also disclosed.

### SUMMARY OF THE INVENTION

In accordance with a first aspect of the present invention there is disclosed a security container for medicines or the like, said container comprising a body and a lid, an electronically activatable locking device having a first part associated with said lid and a second part associated with said body, said first and second parts being movable with respect to each other to lock and unlock said lid with respect to said body, said locking device including an electronic memory store to store data indicative of at least one biomedical attribute of a designated user, a biomedical transducer to transduce said biomedical attribute(s) of a prospective user, and data processing means to receive transduced data from said transducer and compare same with said stored data, said data processing means activating said locking device to unlock said lid only if said transduced and stored data are substantially identical.

In accordance with a second aspect of the present invention there is disclosed a method of dispensing medicines or the like from the above security container, said method comprising the steps of:

(a) having a prospective user engage the biomedical transducer to transduce at least one biomedical attribute,

(b) comparing the transduced medical attribute(s) of the prospective user with the stored medical attribute of the designated user,

(c) if the comparison indicates that there is identity between the prospective user and the designated user opening the locking device, and

(d) not opening the locking device otherwise.

In accordance with a third aspect of the present invention there is disclosed a system of filling. prescriptions for medicines prescribed for a patient by a medical practitioner, said system comprising a plurality of medicine security containers each having a body and a lid, an electronically activatable locking device having a first part associated with said lid and a second part associated with said body, said first and second parts being movable with respect to each other to lock and unlock said lid with respect to said body, said locking device including an electronic memory store to store data indicative of at least one biomedical attribute of a designated user, a biomedical transducer remote from said containers to transduce said biomedical attributes(s) of a prospective user, and each of said containers having a data processing means to receive transduced data from said transducer and compare same with said stored data and activating said locking device to only unlock the lid of the container in the. event that said stored data and said transduced data are substantially identical, data transmission means accessible by a medical practitioner prescribing medicines for said patient to transmit from said medical practitioner to a medicine distribution center data indicating (i) the nature of the medicine prescribed (ii) the contact data of the patient, and (iii) the biomedical attribute data of the patient, and data reception means accessible by said medicine distribution center to receive said transmitted data, whereby on receipt of said transmitted data said medicine distribution center dispenses said prescribed medicine into one of said containers, stores said received biomedical attribute data in the electronic memory store thereof, locks said lid and despatches the locked container to an address of said patient specified in said contact data.

In accordance with a fourth aspect of the present invention there is disclosed a method of filling prescriptions for medicines prescribed for a patient by a medical practitioner, said method comprising the steps of:

(a) said medical practitioner transmitting to a medicine distribution center data indicating (i) the nature of the medicine prescribed, (ii) contact data of the patient, and (iii) biomedical attribute data of the patient,

(b) said medicine distribution center on receipt of the data transmitted in step (a) dispensing said prescribed medicine into one of the last mentioned security containers, storing said received biomedical attribute data in the electronic memory store thereof, locking the lid thereof, and despatching the locked container to an address of said patient specified in said contact data, and

(c) said patient on receipt of said despatched container utilizing the patients biomedical attribute(s) to unlock said container.

### BRIEF DESCRIPTION OF THE DRAWINGS.

Embodiments of the present invention will now be described with reference to the drawings in which:

FIG. 1 is a block diagram of the system elements within the container lid,

FIG. 2 is a block diagram of the system elements within the mobile or portable device,

FIG. 3 is a schematic side elevational view of the container and lid,

FIG. 4 is a schematic plan view of the container lid,

FIG. 5 is a side elevational view of the container and lid,

FIG. 6 is a perspective view from above of the container and lid,

FIG. 7 is an exploded perspective view of the container and lid,

FIG. 8 is a perspective view of a mobile device,

FIG. 9 is a schematic side elevation of the mobile device of FIG. 8,

FIG. 10 is a schematic plan view of the mobile device of FIG. 8,

FIG. 11 is a perspective view showing the operation of the mobile device of FIGS. 8-10,

FIG. 12 is a perspective view showing the operation of an alternative embodiment of a container and lid,

FIG. 13 is a state diagram illustrating the operation of the system elements illustrated in FIGS. 1 and 2,

FIG. 14 is a block diagram illustrating the prior art medicine distribution system, and

FIG. 15 is a block diagram illustrating the medicine distribution system of the preferred embodiment.

### DETAILED DESCRIPTION

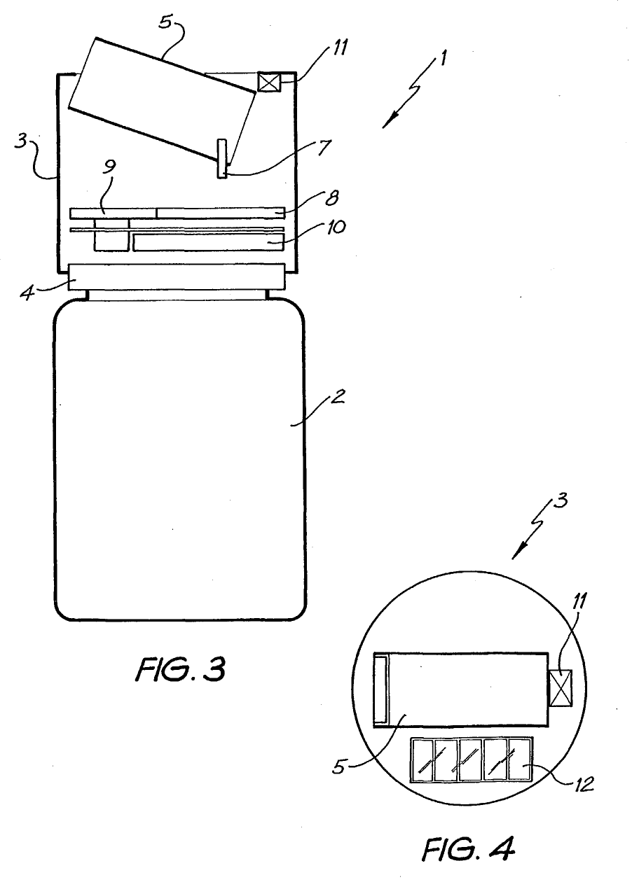

The preferred embodiment of the present invention takes the form of a container 1 illustrated in FIG. 3 having a body 2 and a lid 3. In the embodiment illustrated in FIGS. 3 and 4 the body 2 and lid 3 are fabricated from plastics material and a locking ring 4 secures the lid 3 to the body 2. The lid 3 has a pivotable tube 5 which in its upwardly pivoted position illustrated in FIG. 3 permits tablets, capsules, and like medicines to be loaded into, or dispensed from, the container 1. A spring, not illustrated, urges the tube 5 into its closed rest position.

Located within the lid 3 is a locking actuator 7 which is extendable to block the downward motion of the tube 5 into the open position illustrated in FIG. 3. Thus the actuator 7 is operable to either lock or unlock the tube 5. The preferred form of actuator 7 is an electric solenoid.

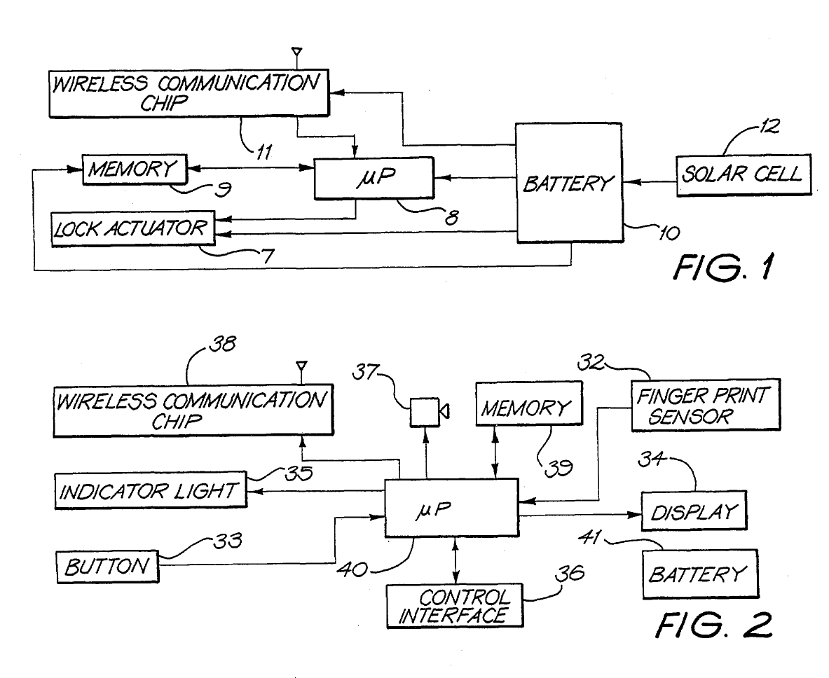

Also located within the lid 3 are a microprocessor 8, a memory 9, a battery or other power storage device 10, a wireless communication clip 11 and a solar cell 12. These components are inter-connected as illustrated in FIG. 1. Essentially a code is stored in the memory 9, and the wireless communication clip receives a coded instruction which is passed to the microprocessor 8, which compares the received code with the stored code. If these are the same the microprocessor 8 activates the locking actuator 7 to move same into its unlocked position, but not otherwise. After a time period determined by the microprocessor 8, the locking actuator 7 is activated to lock the lid 3 once more.

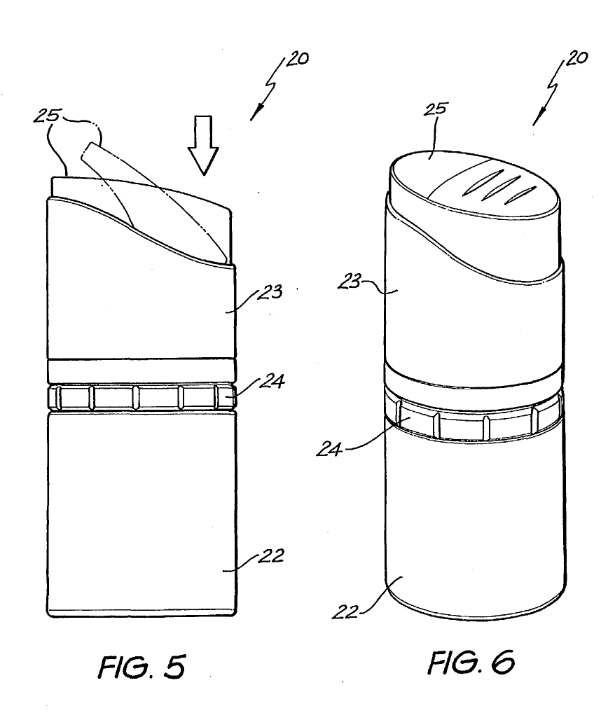

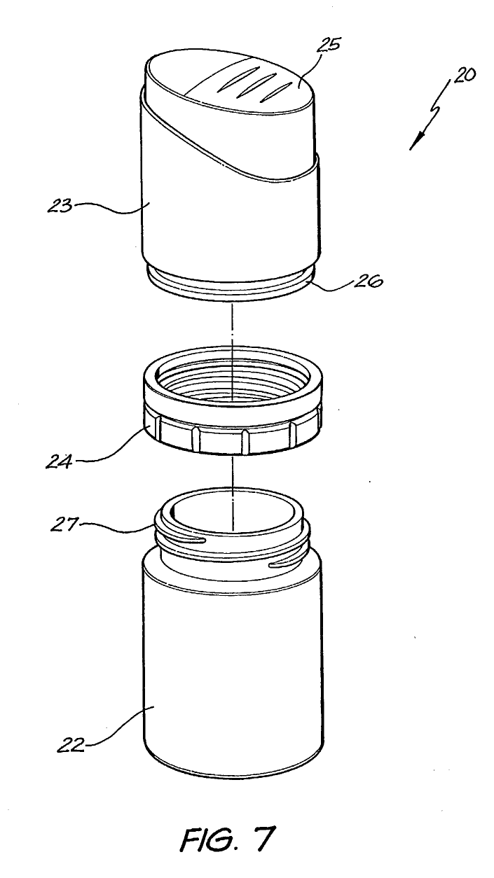

An alternative embodiment of the container 20 is illustrated in FIGS. 5-7. Here the body 22 is essentially as before but the lid 23 is of a different configuration having a pivotable top 25. The lid 23 has an annular flange 26 which engages with a frangible collar 24 which is internally threaded and engages with an external thread 27 on the body 22. Thus the body 22 can be filled with pills, tablets etc, the collar 24 snap engaged with the flange 26 and the collar 24 then screw engaged with the thread 27. In known fashion full engagement of the collar 24 and thread 27 destroys the internal thread on the collar 24 and permits free rotation of the collar 24 relative to both the body 22 and lid 23 with the collar 24 holding both together.

The purpose of the collar 24 is to provide a “fail safe” option should the container 20 have life saving medicines stored within it and the electronics of the unlocking mechanism fail. In this extremely unlikely, but foreseeable, situation the collar 24 can be broken by means of a screw driver, knife, or similar implement to thereby permit the body 22 to be disengaged from the lid 23.

By way of contrast, the container 1 is unable to have its lid 3 removed (except possibly through use of a hacksaw or similar implement). Thus the container 1 is intended for use in all situations except the situation where a life preserving medicine required to be taken at frequent intervals is required to be stored. In these unusual circumstances the container 20 is used instead.

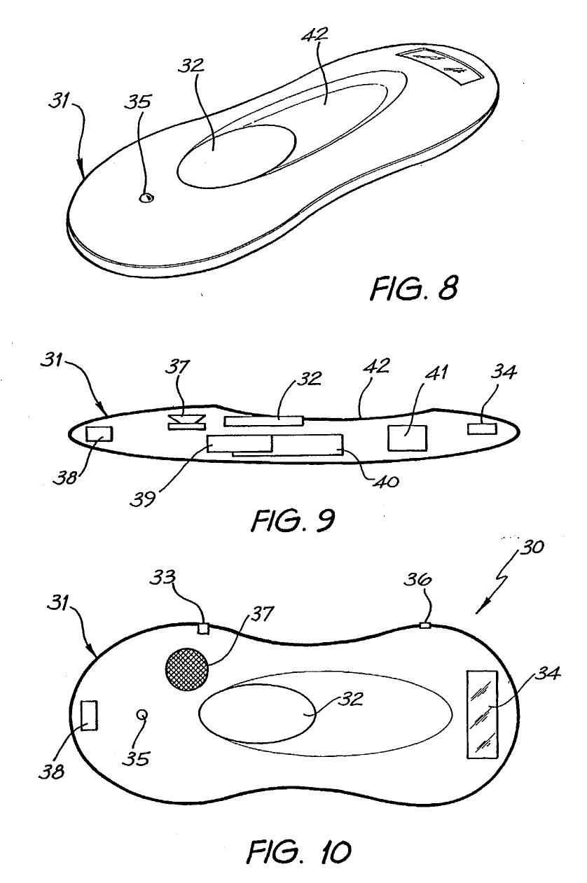

Both the containers 1, 20 are used in conjunction with a mobile or portable key device 30 as illustrated in FIGS. 8-11. The key 30 has a housing 31 on the exterior of which are mounted a fingerprint sensor 32, an on-off button 33, a display 34, an indicator light 35, a control interface 36 and a speaker 37. Within the interior of the housing 31 are located a wireless communication (transmitter) chip 38, a memory 39, a microprocessor 40, and a battery 41. These components are interconnected as illustrated in FIG. 2.

As indicated in FIGS. 8 and 11, the housing 31 is contained so as to be easily grasped in a single hand and a finger resting area 42 is located immediately to the rear of finger print sensor 32.

The control interface 36 is used initially to download a program into the microprocessor 40 which thereafter controls the operation of the key 30. After this initialization, the patient (or in the case of invalid patients their carer or care giver) records a fingerprint via the fingerprint sensor 32 which is stored in the memory 39. The finger print sensor 32 preferably is a capacitive device with a large number of capacitative electrodes which detect the ridges of the human finger and are charged or discharged according to the proximity of the patient's flesh. Thus a “map” of these ridges in terms of voltage and the known spatial arrangement of the capacitive electrodes is produced. This voltage “map” is unique to the patient in the same way as the patient's fingerprint is unique.

Once stored in the memory 39, the encoded fingerprint is transmitted to the microprocessor 8 in the lid 3,23 together with instructions for the data to be stored in memory 9. Thereafter by pressing on the sensor 32 the patient is able to be recognized by the microprocessor 40 matching the incoming voltage map from the sensor 32 with the stored voltage map in the memory 39. This results in the stored data in memory 39 being transmitted via wireless communication chips 38, 11 to the microprocessor 8. If the received data is successfully matched by microprocessor 8 against the data stored in memory 9, the locking actuator 7 is activated to unlock the tube 5. In this way a tablet is able to be dispensed from the container 1.

A full state diagram is provided in FIG. 13 showing all possible logic states. Clearly provision is made for various “housekeeping” tasks including deletion of the previously stored fingerprint and insertion of a new one to cater for such eventualities as a change in a patient's carer. Further, the control interface 36 permits data to be downloaded from the microprocessor 40 so that a history of times of dosage, any failed attempts to open the lid 3, and the like can be logged if desired. This data can be communicated to the patent's doctor and/or the manufacturer/distribution center. This data is particularly relevant for clinical trials, antibiotic resistance campaigns, public health purposes, etc.

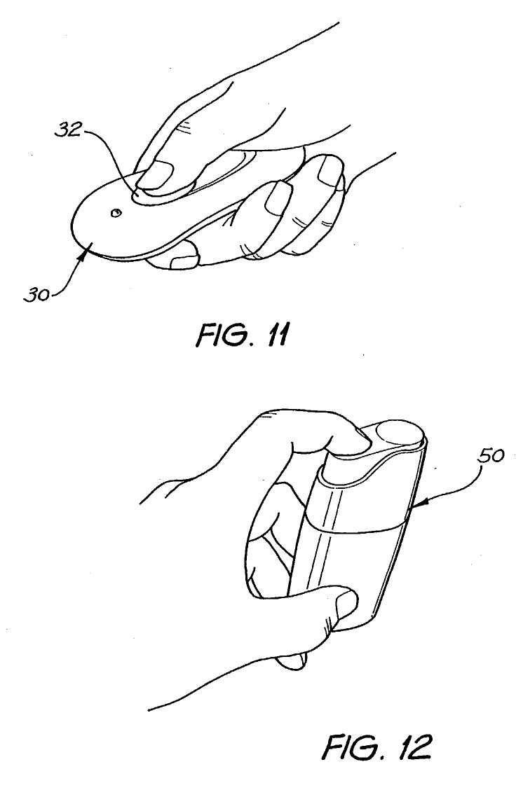

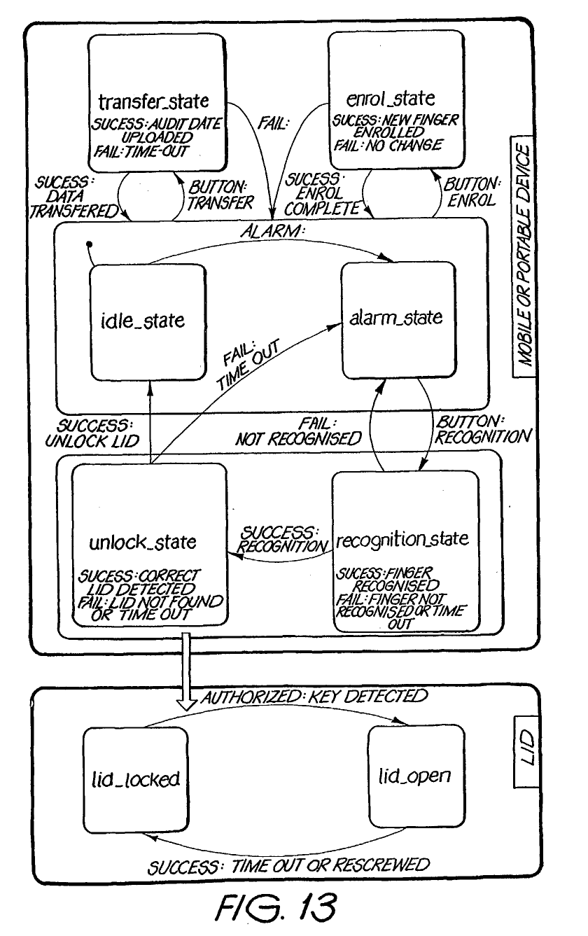

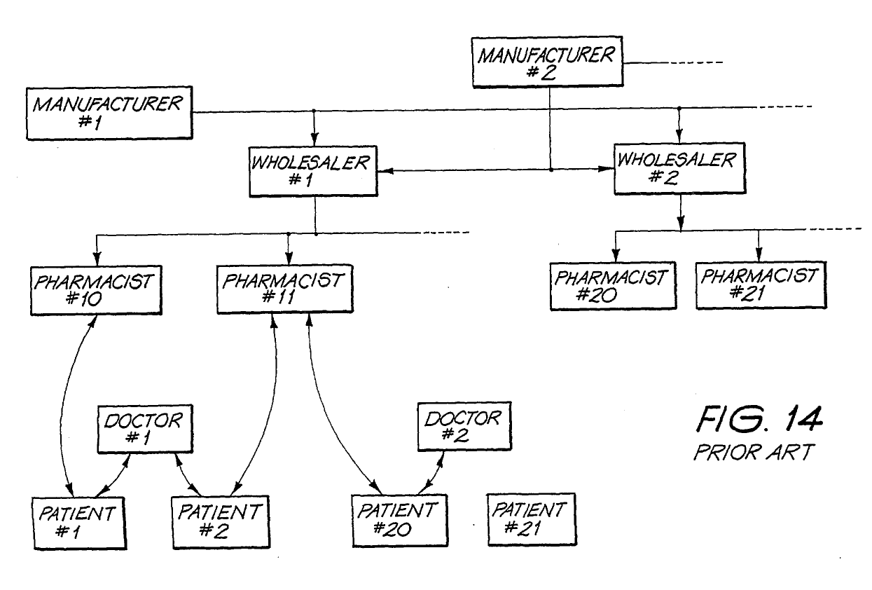

FIG. 12 illustrates an alternative container 50 of the type used to singly dispense artificial sweetner tablets, for example. The known mechanisms of such containers 50 are particularly suitable for use in the present invention since they reliably dispense a single tablet with each operation and their operating mechanism can be easily locked and unlocked with a single plunger, for example.

Since the dispensing of the tablets etc contained within the container 1, 20 is ultimately controlled by the microprocessor 8, for some drugs, such as highly addictive drugs, the microprocessor 8 can be programmed not to dispense more frequently than at a given rate. The single tablet dispensing mechanism is important in this connection. In this way addiction can be prevented or curbed. Similarly, overdosing is substantially eliminated.

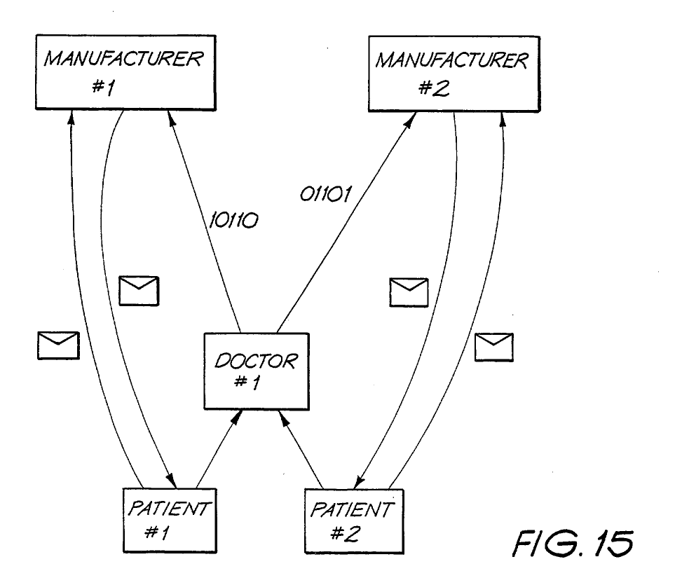

Turning now to FIG. 14, the prior art method of dispensing prescription medicines is schematically illustrated. Different countries use different terms for the operators. For example the pharmacist may be termed chemist, druggist, drug store operator, apothecary, etc. but the essentials of the system in each country are the same. Basically there are large numbers of patients 1, 2 . . . 20, 21 . . . etc who are distributed amongst a smaller number of doctors 1, 2 . . . etc. who prescribe drugs for the patient as a consequence of the patient visiting their doctor. The patient then takes the prescription (or script) to one of a number of pharmacists 10, 11, . . . 20, 21 . . . etc. who dispenses the drugs into a container, or who sells a pre-filled container to the patient. The pharmacists are themselves supplied from a smaller number of wholesalers 1, 2 . . . etc. who are in turn supplied by a small number of manufacturers 1, 2 . . . etc.

If a repeat is required this necessitates either a repeat being initially prescribed or a repeat visit by the patient to the doctor. In either event the patient must make a repeat visit to the pharmacist. When the patient purchases the drugs supplied by the pharmacist these are supplied in the prior art containers and thus suffer from the various problems referred to the Background Art.

The preferred system and method for dispensing drugs in accordance with the present invention is schematically illustrated in FIG. 15 and utilizes the container 1 and key device 30 described above.

The patient visits their doctor as before and is, as before, prescribed a drug. However, the nature of the prescribed drug, the name and address of the. patient, and the result of the patient using the finger print sensor 32 are electronically transmitted by the doctor to the relevant drug manufacturer 1, 2 . . . (or other equivalent entity such as a wholesaler or medicine distribution center). The manufacturer then loads the requisite number of tablets into the container 1 and locks its lid 3, whilst loading the patient's fingerprint into the memory 9. Then the thus initialized container 1 is posted or otherwise delivered to the patient's contact address.

On arrival the container 1 is able to be opened by the patient utilizing the key device 30 and the patient's finger. However, should the container be stolen from the mail, fall into the hands of small children, etc. then container 1 is unable to be opened.

This system and method of dispensing drugs provides a number of advantages. Firstly, drugs are able to be held in a much smaller number of locations thereby reducing the temptation for drug addicts to rob pharmacies. Secondly, repeats can simply be mailed or otherwise dispatched to the patient without the patient making a repeat visit to the pharmacist. Thirdly, the empty containers can be mailed back to the manufacturer (or distribution center) for re-use. Fourthly, the drugs are only transported from the manufacturer or distribution center in patient specific containers so if a shipment from the manufacturer is intercepted or lost the drugs are much more difficult to access.

The foregoing describes only some embodiments of the present invention and modifications, obvious to those skilled in the art, can be made thereto without departing from the present invention. For example, a different biomedical attribute, such as an eye scan, could be used instead of a fingerprint. Further, the sensor 32 can be directly located on the lid 3, 23 so that the key device 30 and lid 3, 23 are effectively combined. Similarly, the container 1, 20 can be provided with a plurality of internal compartments each communicating with a corresponding one of a number of linked tubes 5. With this arrangement a number of different drugs can be stored and simultaneously dosed. Further, the container 1, 20 can be flat and generally rectangular so as to hold one or more flat blister packs. Also liquid medicine dispensing via a lockable valve is possible.

The term “comprising” as used herein is used in the sense of “having” or “including” and not in the sense of “consisting only of”.

1. A security container for medicines or the like, said container comprising a body and a lid, an electronically activatable locking device having a first part associated with said lid and a second part associated with said body, said first and second parts being movable with respect to each other to lock and unlock said lid with respect to said body, said locking device including an electronic memory store to store data indicative of at least one biomedical attribute of a designated user, a biomedical transducer to transduce said biomedical attribute(s) of a prospective user, and data processing means to receive transduced data from said transducer and compare same with said stored data, said data processing means activating said locking device to unlock said lid only if said transduced and stored data are substantially identical.

2. The container as claimed in claim 1 wherein said biomedical transducer is contained in said lid.

3. The container as claimed in claim 1 wherein said biomedical transducer is contained in a remote device separate from said container, said remote device includes a transmitter means connected to said transducer means to transmit the transduced data generated, and said container includes a receiver means connected to said data processing means to receive transduced data transmitted from said remote device.

4. The container as claimed in any one of claims 1-3 wherein said biomedical attribute is a fingerprint.

5. The container as claimed in claim 4 wherein said transducer is selected from the group consisting of capacitive transducers and friction transducers.

6. A method of dispensing medicines or the like from the security container as claimed in claim 1, said method comprising the steps of:
(a) having a prospective user engage the biomedical transducer to transduce at least one biomedical attribute,
(b) comparing the transduced medical attribute(s) of the prospective user with the stored medical attribute of the designated user,
(c) if the comparison indicates that there is identity between the prospective user and the designated dser opening the locking device, and
(d) not opening the locking device otherwise.

7. The method of dispensing medicines as claimed inc claim 6 including the further step of re-locking said lid after dispensing only a dosage quantity of medicine stored in said container.

8. The method of dispensing medicines as claimed in claim 7 wherein on each occasion for which a dose of said medicine is required steps (a)-(c) are repeated.

9. The method of dispensing medicines as claimed in any one of claims 6-8 wherein the designated user is the patient for whom the medicine has be prescribed by a medical practitioner.

10. The method of dispensing medicines as claimed in any one of claims 6-8 wherein the designated user is a carer of the patient for whom the medicine has been prescribed by a medical practitioner.

11. A system of filling prescriptions for medicines prescribed for a patient by a medical practitioner, said system comprising a plurality of medicine security containers each having a body and a lid, an electronically activatable locking device having a first part associated with said lid and a second part associated with said body, said first and second parts being movable with respect to each other to lock and unlock said lid with respect to said body, said locking device including an electronic memory store to store data indicative of at least one biomedical attribute of a designated user, a biomedical transducer remote from said containers to transduce said biomedical attributes(s) of a prospective user, and each of said containers having a data processing means to receive transduced data from said transducer and compare same with said stored data and activating said locking device to only unlock the lid of the container in the event that said stored data and said transduced data are substantially identical, data transmission means accessable by a medical practitioner prescribing medicines for said patient to transmit from said medical practitioner to a medicine distribution center data indicating (i) the nature of the medicine prescribed (ii) the contact data of the patient, and (iii) the biomedical attribute data of the patient, and data reception means accessable by said medicine distribution center to receive said transmitted data, whereby on receipt of said transmitted data said medicine distribution center dispenses said prescribed medicine into one of said containers, stores said received biomedical attribute data in the electronic memory store thereof, locks said lid and despatches the locked container to an address of said patient specified in said contact data.

12. The system for filling prescriptions as claimed in claim 11 including a plurality of biomedical transducers, one for each patient.

13. The system for filling prescriptions as claimed in claim 12 wherein each said doctor has one of said biomedical transducers.

14. The system for filling prescriptions as claimed in any one of claims 11-13 wherein a plurality of said containers are provided for each patient and for any repeat of a prescription a further locked medicine containing one of said containers is despatched to said patient.

15. A method of filling prescriptions for medicines prescribed for a patient by a medical practitioner, said method comprising the steps of:
(a) said medical practitioner transmitting to a medicine distribution center data indicating (i) the nature of the medicine prescribed, (ii) contact data of the patient, and (iii) biomedical attribute data of the patient,
(b) said medicine distribution center on receipt of the data transmitted in step (a) dispensing said prescribed medicine into one of the security containers as claimed in claim 3, storing said received biomedical attribute data in the electronic memory store thereof, locking the lid thereof, and despatching the locked container to an address of said patient specified in said contact data, and
(c) said patient on receipt of said despatched container utilizing the patients biomedical attribute(s) to unlock said container.

16. The method of filling prescriptions as claimed in claim 15 including the further steps of:
(d) said medical practitioner transmitting data to said medicine distribution center indicating that said prescription is to be repeated,
(e) said patient contacting said medicine distribution center requesting a repeat of the prescription, and
(f) said medicine distribution center repeating step (b).

17. The method of filling prescriptions as claimed in claim 16 wherein said patient on carrying out step (e) returns empty to the medicine distribution center the container despatched to the patient in step (b).

18. The method of filling prescriptions as claimed in any one of claims 15-17 wherein the biomedical attribute data transmitted and stored is the biomedical attribute data of a carer of said patient.
